(19) United States
(12) Patent Application Publication
(10) Pub. No.: US 2012/0025403 A1
(43) Pub. Date: Feb. 2, 2012

(54) DESIGN APPARATUS OF SEMICONDUCTOR DEVICE, DESIGN METHOD OF SEMICONDUCTOR DEVICE, AND SEMICONDUCTOR DEVICE

(75) Inventor: Shinji YOKOGAWA, Kanagawa (JP)

(73) Assignee: RENESAS ELECTRONICS CORPORATION, Kawasaki-shi (JP)

(21) Appl. No.: 13/194,607

(22) Filed: Jul. 29, 2011

(30) Foreign Application Priority Data
Jul. 30, 2010 (JP) 2010-172600
Feb. 4, 2011 (JP) 2011-023313

(51) Int. Cl. H01L 23/48; G06F 17/50

(52) U.S. Cl. 257/786; 716/129; 257/E23.01

(57) ABSTRACT

A design method of a semiconductor device includes four steps. The first step is of arranging grid wiring which includes a plurality of wiring lines arranged in parallel to each other and a plurality of vias connecting the plurality of wiring lines with each other. The second step is of arranging a plurality of internal circuits connected to the grid wiring. The third step is of calculating a current density of a current flowing in the grid wiring by the plurality of internal circuits. The fourth step is of dividing each of the plurality of wiring lines into portions each having a wiring length such that electromigration corresponding to the current density is suppressed.

### CROSS REFERENCE TO RELATED APPLICATIONS

The present application claims the benefit of patent application numbers 2011-023313 filed in Japan on Feb. 4, 2011 and 2010-172600 filed in Japan on Jul. 30, 2010, the subject matters of which are hereby incorporated herein by reference.

### BACKGROUND

1. Field of the Invention

The present invention relates to a design apparatus of a semiconductor device, a design method of a semiconductor device, and a semiconductor device, and more particularly, relates to a design apparatus of a semiconductor device, a design method of a semiconductor device, and a semiconductor device, each of which improves reliability of a wiring line.

2. Description of Related Art

In a wiring line of a semiconductor device, it is known that the electromigration (hereinafter referred to as EM) sometimes occurs. Recently, in the semiconductor device, since a size of the wiring line is reduced, deterioration of reliability due to the EM has been concerned. The disconnection of a wiring line caused by the EM occurs in, especially, a wiring line through which a direct current (hereinafter referred to as DC) or a pulsed direct current (hereinafter referred to as PDC) flows.

The semiconductor device includes a power source grid extended throughout the inside of a chip in a mesh shape to supply an electric current into the inside of the chip. In the power source grid, based on a driving power and an operation frequency of an internal circuit arranged in the inside of the mesh, a current value (DC and PDC) flowing in the vicinity of the internal circuit varies. Accordingly, the power source grid and the internal circuit are designed, for example, in the following manner. At first, a wiring line of a test structure having a layout in a worst case as a most disadvantageous case of the reliability is prepared. Next, a life test is carried out in the wiring line of the test structure. Subsequently, on the basis of the result of the life test, a limited current value (the worst case current limitation value) that satisfies a predetermined life is set. Then, the power source grid and the internal circuit arranged in the inside of the mesh are designed so as not to exceed the limited current value.

The limited current value in the above-mentioned design is a limited current value in the worst case (the worst case current limitation value). Accordingly, the above-mentioned design will be design that actually has an excessive margin. Additionally, in the case where it is required to exceed the limited current in order to achieve a function of the internal circuit and the like, layout design requires to be changed so that the EM can be avoided by increasing a width of the corresponding wiring line to reduce a current density. Due to the above-mentioned change of the layout design, an integration degree of the internal circuit is reduced to increase a chip size.

As a design correction method for a case where the layout design requires to be changed due to the current value exceeding the limited current value (the worst case current limitation value) for dealing with the EM in the above-mentioned worst case, Patent literature 1 (Japanese patent publication JP-A-Heisei 11-97541) describes a method of increasing the branching number of wiring lines so as to avoid an error in a position where the error occurs in verification after the layout design. That is, a design method of a semiconductor integrated circuit of Patent literature 1 carries out: the layout of a plurality of functional blocks each having an arbitrary function; and the routing between the functional blocks. In the design method of the semiconductor integrated circuit, current densities of currents flowing in all wiring lines that connect between the functional blocks are calculated by a circuit simulation, respectively. It is judged whether or not each of the current densities is within a preliminarily determined standard value. Regarding the wiring line exceeding the standard value, the number of wiring lines required in each branching of the wiring line is calculated so as to fall within the standard value. The routing is carried out again in each branching at the number of wiring lines.

In addition, Patent literature 2 (Japanese patent publication JP 2002-217296A: corresponding to U.S. Pat. No. 6,971,082(B2)) describes a method of: calculating a current amount at each branching of a wiring line; and increasing a wiring width in wiring data causing an error. That is, a wiring design method of Patent literature 2 electrically and mutually connects a plurality of functional blocks on a semiconductor integrated circuit. In the wiring design method, a wiring branching point between the plurality of functional blocks is obtained (a first connection information acquisition step). A current density at the wiring branching point is obtained (a second connection information acquisition step). It is judged whether or not the current density exceeds a predetermined limited value (a judgment step). On the basis of the result of the judgment, a process to reduce the current density is carried out to a predetermined wiring portion having the wiring branching point as an end where the current density exceeds the limited value (a reduction process step).

On the other hand, it is known that a wiring lifetime is extended in the case where both ends of the wiring line are terminated by vias or contacts. For example, in Non-patent literature 1 (A. Blech, Journal of Applied Physics, Vol. 47, p. 1203 (1976)), the following fact is described. When a structure where both ends of the wiring line are terminated by vias or contacts is employed, a tensile stress is generated on an upstream side and a compressive stress is generated on a downstream side due to an atom transport of the EM (transfer from a cathode to an anode). That is, a difference of the internal stress (a stress gradient) is generated in the inside of the wiring line. The difference of the internal stress serves as an atom transport driving force in an opposite direction to the EM (a back flow stress: a force heading from the anode to the cathode). Due to the difference of the internal stress, the atom transport by the EM is suppressed, and thus the EM becomes hard to occur. The shorter the wiring line becomes, the larger the difference of the internal stress becomes. Accordingly, the shorter the wiring line becomes, the more the atom transport by the EM is suppressed under the same current density, and thus the lifetime of the wiring line becomes longer. When the wiring line becomes shorter than a certain threshold value, a void caused by the EM is not generated and growing. That is, the EM substantially stops being generated, and the lifetime of the wiring line reaches an infinite length.

Non-patent literature 2 (R. G. Filippi, et al., Applied Physics letters, Vol. 69, p. 2350 (1996)) and Non-patent literature 3 (R. G. Filippi, et al., Journal of Applied Physics, Vol. 91, p. 5787 (2002)) propose to give a larger allowable current than that of the worst case to the short wiring line by applying this phenomenon (hereinafter referred to as a back flow effect). In addition, Non-patent literature 4 (S. P. Hau-Riege, et al., Journal of Applied Physics, Vol. 88, p. 2382 (2000)) reports that the back flow effect also can be applied to a bent or branched wiring line.

In relation, Patent literature 3 (JP 2003-133377 A (corresponding U.S. Pat. No. 6,884,637(B2))) discloses an inspection pattern of a multi-layer wiring structure, a semiconductor device having the inspection pattern, an inspection method of the semiconductor device, and an inspection system of the semiconductor device. The inspection pattern detects a latent defect on the multi-layer wiring structure formed in a semiconductor wafer. The inspection pattern includes: a plurality of lower-layer wiring lines; a plurality of upper-layer wiring lines; an insulating layer; a plurality of contact units; and a pair of electrode terminals. The plurality of lower-layer wiring lines is arranged with keeping an interval with each other. The plurality of upper-layer wiring lines is arranged with keeping an interval with each other. The insulating layer is provided between: the plurality of upper-layer wiring lines and the plurality of lower-layer wiring lines. The plurality of contact units electrically connect the plurality of upper-layer wiring lines to the plurality of lower-layer wiring lines so as to configure a contact chain where the plurality of upper-layer wiring lines and the plurality of lower-layer wiring lines are alternatively connected in series. The pair of electrode terminals is electrically connected to both ends of the contact chain. Of the plurality of contact units, lengths of the plurality of lower-layer wiring lines, lengths of the plurality of upper-layer wirings, and positions of the contact units are set so that a clearance between the contact units adjoining with each other along a longitudinal direction of the lower-layer wiring line or a longitudinal direction of the upper-layer wiring line is 50 μm or less.

The inventor has now discovered the following facts. In the above-mentioned Patent literatures 1 and 2, it is judged in a preliminarily-determined layout whether or not the reliability satisfies a required value based on whether or not the current density obtained from a layout characteristic and a circuit function exceeds the current limitation value (the worst case current limitation value) obtained in accordance with a model proposed in the papers. Then, in the case of exceeding the current limitation value, the layout is changed in the exceeding position. In other words, in the above-mentioned worst case, the current limitation value is substantially extended by changing the layout of the wiring line so that the current value cannot be limited. In this case, in the position exceeding the current limitation, the changing of wiring configuration such as the extension of wiring width and the increasing of the number of wiring lines is required as the layout change.

FIG. 1 is a schematic diagram showing a semiconductor device which has now been designed by the inventor in order to describe problems of the present invention. A semiconductor device 101 includes: a power source grid 110; and a plurality of internal block circuit 104 (for example, 104a to 104d). The power source grid 110 includes power source wiring lines 102 arranged in a lattice shape. A wiring width of each power source wiring line 102 is, for example, initially W₀. As each internal block circuit 104 a functional block configuring a logical circuit and the like is exemplified, and each internal block circuit 104 is arranged in the power source grid 110. The internal block circuits 104 are connected to the power source grid 110 via power source leading wiring lines 103. In the internal block circuits 104a to 104d, the power consumptions are not the same. For example, the internal block circuits 104a and 104d consume a low power, the internal block circuit 104c consumes a middle power, and the internal block circuit 104b consumes a high power. On this occasion, even when the conceivable maximum current value flows through the power source wiring lines 102, in order not to exceed the limited current density in consideration of operation rates of the internal blocks 104a to 104d with different power consumptions, it is required for each power source wiring line 102 to have a thicker wiring width than the normal W₀. Or, it is required to increase the number of wiring lines by adding wiring lines. In the example of the drawing, the wiring width is expanded to W₁ (>W₀).

Correction of the configuration of a wiring line such as extension of a wiring width and increasing of the number of wiring lines has problems: that an area of the circuit becomes large; that a design time is lengthened by repeating correction and confirmation; that the configuration is hard to be corrected in a large-scale circuit when balancing with other parts should be considered; and the like.

### SUMMARY

The present invention seeks to solve one or more of the above problems, or to improve upon those problems at least in part.

In one embodiment, a design method of a semiconductor device includes: arranging grid wiring which includes a plurality of wiring lines arranged in parallel to each other and a plurality of vias connecting the plurality of wiring lines with each other; arranging a plurality of internal circuits connected to the grid wiring; calculating a current density of a current flowing in the grid wiring by the plurality of internal circuits; and dividing each of the plurality of wiring lines into portions each having a wiring length such that electromigration corresponding to the current density is suppressed.

In another embodiment, a non-transitory computer-readable recording medium in which a computer-readable program code is stored for realizing a design method of a semiconductor device, the design method includes: arranging grid wiring which includes a plurality of wiring lines arranged in parallel to each other and a plurality of vias connecting the plurality of wiring lines with each other; arranging a plurality of internal circuits connected to the grid wiring; calculating a current density of a current flowing in the grid wiring by the plurality of internal circuits; and dividing each of the plurality of wiring lines into portions each having a wiring length such that electromigration corresponding to the current density is suppressed.

In another embodiment, a design apparatus of a semiconductor device includes: a grid wiring section configured to arrange grid wiring which includes a plurality of wiring lines arranged in parallel to each other and a plurality of vias connecting the plurality of wiring lines with each other; a circuit placement section configured to arrange a plurality of internal circuits connected to the grid wiring; a current analysis section configured to calculate a current density of a current flowing in the grid wiring by the plurality of internal circuits; and a layout adjustment section configured to divide each of the plurality of wiring lines into portions each having a wiring length such that electromigration corresponding to the current density is suppressed.

In another embodiment, a semiconductor device includes: grid wiring configured to include a plurality of wiring lines arranged in parallel to each other and a plurality of vias connecting the plurality of wiring lines with each other; and a plurality of internal circuits configured to be connected to the grid wiring; wherein a current flows in the grid wiring by the plurality of internal circuits, wherein each of the plurality of wiring lines is divided into portions each having a wiring length such that electromigration corresponding to a current density of the current is suppressed.

According to the present invention, problems such as increasing of a circuit area, lengthening of a design time, and a difficulty of correction in a case of a large-scale circuit are not caused, and thus a wiring line where occurrence of the EM is significantly suppressed can be designed.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a schematic view showing a semiconductor device designed by the inventor in order to describe problems of the present invention;

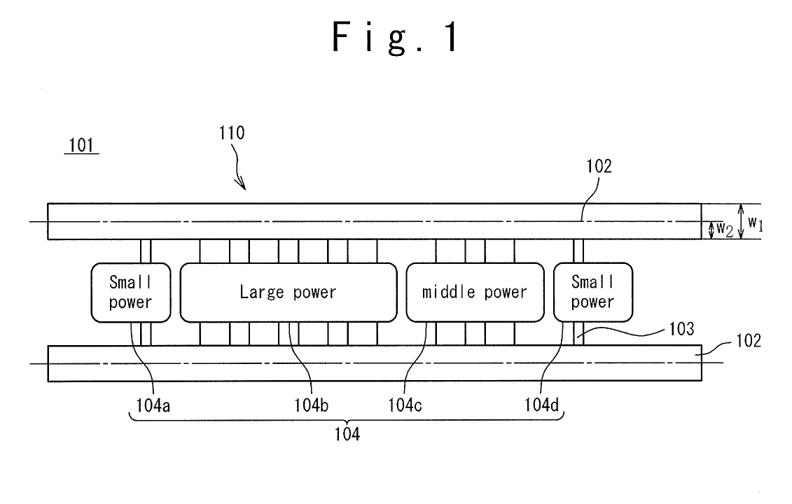

FIG. 2 is a block diagram showing a configuration of a design apparatus of a semiconductor device according to an embodiment of the present invention;

FIG. 3A is a plane view showing an example of a configuration of a semiconductor device according to the embodiment of the present invention;

FIG. 3B is a sectional view showing the example of the configuration of the semiconductor device according to the embodiment of the present invention;

FIG. 3C is a sectional view showing the example of the configuration of the semiconductor device according to the embodiment of the present invention;

FIG. 3D is a sectional view showing the example of the configuration of the semiconductor device according to the embodiment of the present invention;

FIG. 4 is a flowchart showing an operation of the design apparatus of the semiconductor device (a design method of the semiconductor device) according to the embodiment of the present invention;

FIG. 5A is a plane view showing an example of a configuration of the semiconductor device in each design step using the design apparatus of the semiconductor device according to the embodiment of the present invention;

FIG. 5B is a sectional view showing the example of the configuration of the semiconductor device in each design step using the design apparatus of the semiconductor device according to the embodiment of the present invention;

FIG. 6 is a plane view showing the example of the configuration of the semiconductor device in each design step using the design apparatus of the semiconductor device according to the embodiment of the present invention;

FIG. 7A is a plane view showing the example of the configuration of the semiconductor device in each design step using the design apparatus of the semiconductor device according to the embodiment of the present invention; and

FIG. 7B is a sectional view showing the example of the configuration of the semiconductor device in each design step using the design apparatus of the semiconductor device according to the embodiment of the present invention.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Referring to attached drawings, a design apparatus of a semiconductor, a design method of a semiconductor device, and a semiconductor device according to an embodiment of the present invention will be described below.

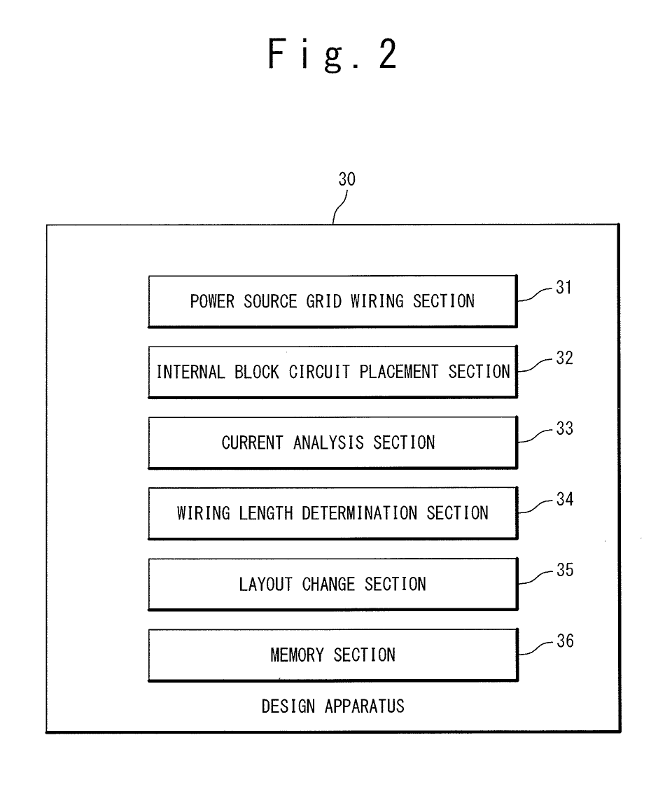

FIG. 2 is a block diagram showing a configuration of the design apparatus of the semiconductor device according to the embodiment of the present invention. The design apparatus 30 carries out a wiring design of the semiconductor device by using an automatic placement and routing tool for a semiconductor device. In the designing of wiring lines (for example, designing of a power source grid), the design apparatus 30 determines wiring lines to locally optimize them based on the assumption of application of the back flow effect.

The design apparatus 30 is an information processing device such as a computer, and includes a CPU (central processing unit), a memory device, an input device, an output device, and an interface, which are not shown. The CPU, the memory device, the input device, the output device, and the interface are connected so as to mutually transmit and receive information through a bus and/or a cable. The memory device is exemplified by a RAM (Random Access Memory), a ROM (Read Only Memory), and an HDD (Hard Disk Drive). A keyboard and a mouse are exemplified as the input device. A display and a printer are exemplified as the output device. The interface is connected to an external computer, a memory device, a storage medium reading device, and the like so as to realize an interactive communication with them.

The CPU expands a computer program installed, for example, from the storage medium to the HDD via the interface onto the RAM. Then, the CPU executes the expanded computer program to realize an information processing of the computer program, with controlling hardware such as the memory device, the input device, the output device as needed. The memory device records the computer program, and records information used by the CPU and information generated by the CPU. The input device outputs information generated through an operation of a user to the CPU and the memory device. The output device outputs the information generated by the CPU and the information of the memory device in a visibly perceptible manner to a user.

The design apparatus 30 includes a power source grid wiring section 31, an internal block circuit placement section 32, a current analysis section 33, a wiring length determination section 34, and a layout change section 35, which are computer programs. These sections may be included in the automatic placement and routing tool for a design of a semiconductor device. Moreover, the design apparatus 30 includes a memory section 36 such as the above-mentioned memory device or storage medium reading device.

On the basis of placement information and connection information of the semiconductor device, the power source grid wiring section 31 arranges grid wiring (a power source grid). The grid wiring (the power source grid) includes: a plurality of wiring lines arranged in parallel with each other (for example, the power source wiring lines); and a plurality of vias connecting the plurality of wiring lines with each other. Then, the power source grid wiring section 31 creates layout data showing the arrangement.

On the basis of the placement information and the connection information of the semiconductor device, the internal block circuit placement section 32 arranges a plurality of internal block circuit (for example, logical circuits) connected to the power source grid. Then, the internal block circuit placement section 32 creates layout data showing the arrangement.

The current analysis section 33 generates a netlist on the basis of the layout data showing the arrangement of the power source grid and the internal block circuits, and executes a circuit simulation to calculate a current density of a current flowing through the power source grid (for example, the power source wiring line, an upper-layer wiring line, a lower-layer wiring line, and the via) due to the plurality of internal block circuits.

The wiring length determination section 34 determines a wiring length of each of the plurality of wiring lines (for example, the upper-layer wiring line and the lower-layer wiring line) so as to realize a wiring length in which the electromigration depending on the current density can be suppressed. Specifically, the wiring length of each of the plurality of wiring lines is determined so that the product of the current density and the wiring length can be a preliminarily-set value (described later) or lower.

On the basis of the determined wiring length of each of the plurality of wiring lines, the layout change section 35 divides each of the plurality of wiring lines. Then, the layout change section 35 changes the layout data so as to correspond to the division of the each of the plurality of wiring lines.

Here, since having a function of layout adjustment, the wiring length determination section 34 and the layout change section 35 can be seen totally as a layout adjustment section.

The memory section 36 stores: the placement information and the connection information of the semiconductor device; the layout data; the netlist, a library; the worst case current limitation value. In addition, the memory section 36 stores a relation (expression (1)) between the wiring length and the current density of power source wiring line described later.

The design apparatus 30 may be included in a circuit design apparatus of a semiconductor device.

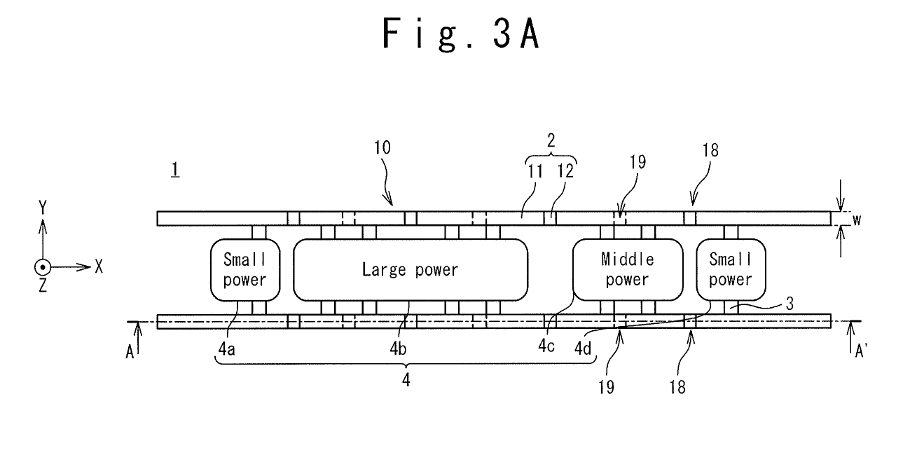

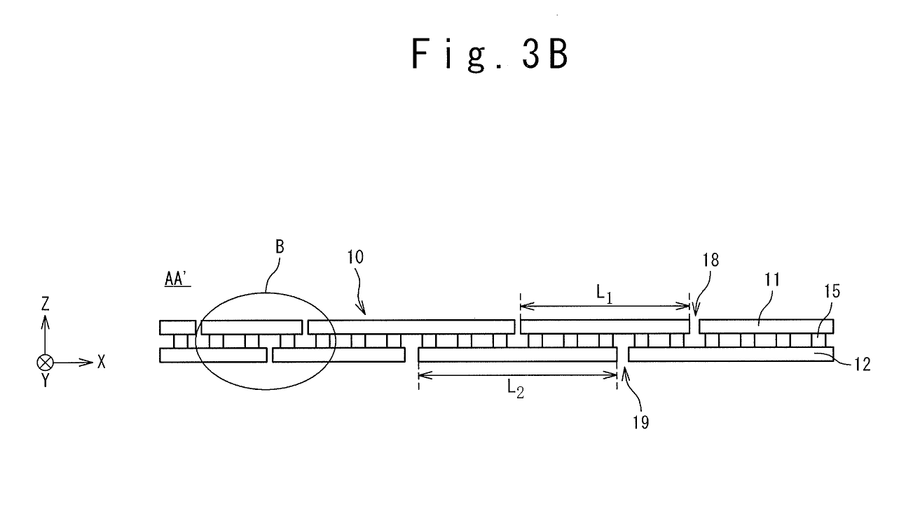

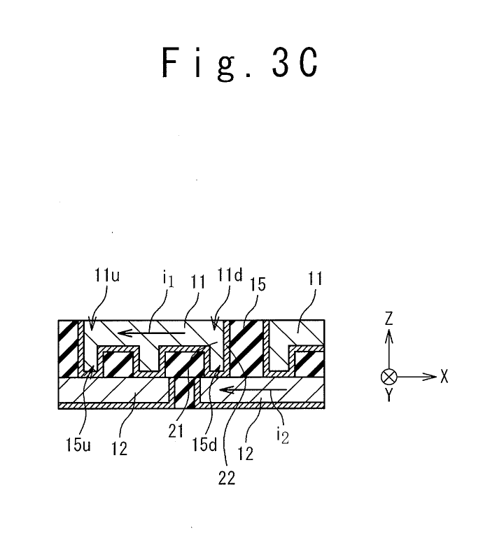

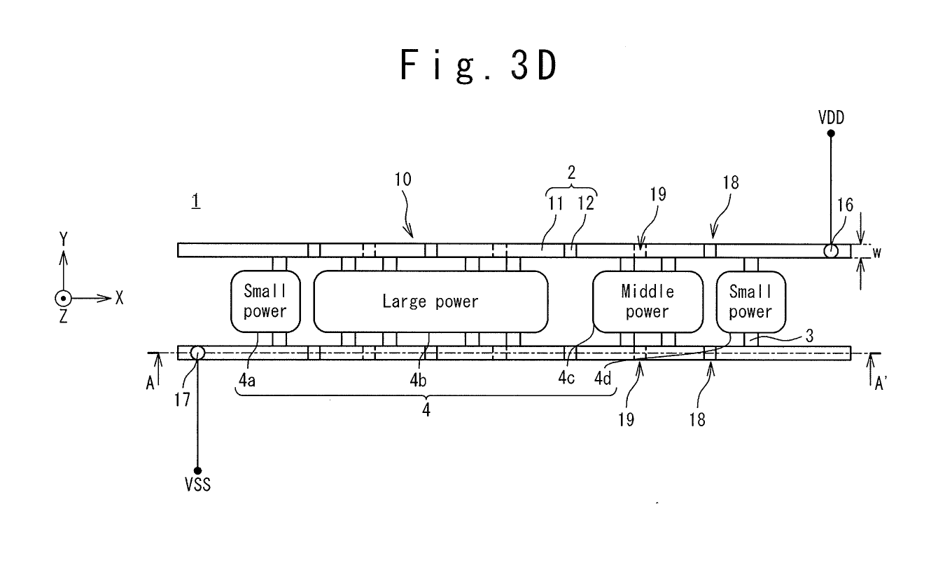

FIG. 3A to FIG. 3D are schematic views showing one example of a configuration of the semiconductor device according to the embodiment of the present invention, respectively. The semiconductor device is designed by the design apparatus of the semiconductor device of FIG. 2. However, FIG. 3A and FIG. 3D show plane views, FIG. 3B shows an AA′ sectional view in FIG. 3A, and FIG. 3C shows an enlargement view of B-part of FIG. 3B, respectively. The semiconductor device 1 includes a power source grid 10 and a plurality of internal block circuits 4 (for example, 4a to 4d).

The power source grid (the grid wiring) 10 is wiring lines for supplying the power source voltage VDD and the ground voltage VSS to the internal block circuits 4. When the power source voltage VDD and the ground voltage VSS are supplied, a current depending on operations of the internal block circuits 4 flows through the power source grid 10. The power source grid 10 includes a plurality of power source wiring lines 2 arranged in a lattice shape (the drawing shows a part of them). As shown in FIG. 3D, the power source grid 10 includes: a power source terminal 16 connected to a power source supplying the power source voltage VDD; or a ground terminal 17 supplying the ground voltage VSS.

The internal block circuit 4 includes, for example, a functional block constituting the logical circuit and the like, and is arranged in the power source grid 10. The internal block circuit 4 is connected to at least one of the power source wiring lines 2 of the power source grid 10 via the power source leading wiring lines 3. The internal block circuits 4a to 4d do not necessarily consume the same power. For example, the internal block circuits 4a and 4d consume a low power, the internal block circuit 4c consumes a middle power, and the internal block circuit 4b consumes a high power.

The power source wiring lines 2 of the power source grid 10 supply voltages (currents) to the internal block circuits 4. A wiring width of each power source wiring line 2 is, for example, W. The power source wiring line 2 includes: an upper-layer wiring line 11 and a lower-layer wiring line 12; and a plurality of vias (through holes) 15. The upper-layer wiring line 11 and the lower-layer wiring line 12 are arranged in parallel with each other. The plurality of vias (through holes) 15 connects the upper-layer wiring line 11 and the lower-layer wiring line 12 each other (in parallel). In this manner, the power source wiring line 2 is configured to be a double-layer wiring line, and thus can be considered as one wiring line composed of two wiring lines in two layers. Meanwhile, in FIG. 3B, a wiring structure including two layers of the upper-layer wiring line 11 and the lower-layer wiring line 12 is shown; however, the power source wiring line 2 may be a triple or more-layered wiring line composed of three or more wiring lines in three or more-layers. In addition, in a planar view, the upper-layer wiring line 11 and the lower-layer wiring line 12 of the power source wiring line 2 overlap with each other. However, it is not necessarily for the upper-layer wiring line 11 and the lower-layer wiring line 12 to completely overlap in the planar view with each other. For example, it is allowable that the upper-layer wiring line 11 overlaps partially with the lower-layer wiring line 12 in the planar view.

In the power source wiring line 2, in accordance to the power consumption and the operation rates of each of the internal block circuits 4, based on a condition described later, division positions (division positions 18 or division positions 19) are provided in the power source wiring line 2 (the upper-layer wiring line 11 or the lower-layer wiring line 12) in layers where the power source leading wiring lines 3 are formed. This is because the wiring lengths of the upper-layer wiring line 11 and the lower-layer wiring line 12 can take lengths that the elecromigration based on the current density of the current flowing through them is suppressed. In this case, since at least one continuous path of the power source wiring line is formed via the upper-layer wiring line 11, the lower-layer wiring line 12, and the vias 15 even if there are the division positions 18 and 19 in the upper-layer wiring line 11 and the lower-layer wiring line 12, the wiring lines can serve as one wiring line as a whole. In this manner, the function of the power source grid 10 is never impaired. As described above, the upper-layer wiring line 11 and the lower-layer wiring line 12 are divided so that the power source voltage VDD or the ground voltage VSS can be supplied to the internal block circuits 4 via the power source leading wiring lines 3 from the power source wiring line 2. In other words, the power source wiring line 2 is divided so that at least one current path can be formed between: the power source leading wiring lines 3 and a power source terminal to which the power source voltage VDD is supplied or a ground terminal to which the ground voltage VSS is supplied. For example, through a plurality of wiring lines (the upper-layer wiring line 11, the lower-layer wiring line 12, and the like) constituting the power source wiring line 2 and the vias 15 connecting the plurality of wiring lines each other, the plurality of wiring lines are divided so that at least one current path connected to both ends of the power source wiring line 2 can be formed.

Here, the wiring length in which the electromigration in the power source wiring line 2 can be suppressed will be described.

Referring to FIG. 3C, the wiring length will be described using the upper-layer wiring line 11 as an example. In FIG. 3C, a case where: the both ends of the upper-layer wiring line 11 are terminated by the vias 15u and 15d; and the current (the current density i₁) flows from the via 15d to the via 15u will be considered. In addition, it is assumed that the upper layer wiring line 11 is formed of a metal film 21 and a barrier film 22. On this occasion, material atoms of the metal film 21 is transported from one end portion 11u to the other end portion 11d of the upper-layer wiring line 11 due to the atom transport of the EM. However, the via 15d connected to the end portion 11d is under a state where the moving of the material atoms of the metal film 21 is inhibited by the barrier film 21. As the result, a tensile stress is generated in the end portion 11u of the upper-layer wiring line 11 and the via 15u, and a compressive stress is generated in the end portion 11d and the via 15d. That is, a difference of the internal stress (a stress gradient) is generated in the inside of the upper-layer wiring line 11. The difference of the internal stress serves as an atom transport driving force of an opposite direction to the EM (the back flow stress). Due to the difference of the internal stress, the atom transport by the EM is suppressed, and thus the EM becomes hard to occur. The shorter the wiring length L₁ becomes, the larger the difference of the internal stress becomes. Accordingly, the shorter the wiring length L becomes, the more the atom transport by the EM is suppressed under the same current density i₁, and thus the lifetime of the upper-layer wiring line 11 becomes longer. When the wiring length L₁ becomes a certain threshold value or less, a void due to the EM is not generated and growing. That is, the EM substantially stops being generated, and the lifetime of the wiring line reaches an infinite length. The following expression (1) shows this relationship. This can be similar to the lower-layer wiring line 12. Specifically, in the case of the lower-layer wiring line 12, since the both ends of the lower-layer wiring line 12 is terminated by the barrier film in the same layer, the same effect as the upper-layer wiring line 11 can be obtained.

The division positions 18 and 19 are set as follows so that the wiring lengths of the upper-layer wiring line 11 and the lower-layer wiring line 12 can be the wiring length where the electromigration can be suppressed.

The upper-layer wiring line 11 and the lower-layer wiring line 12 are divided at the division positions 18 and 19, respectively, so as to have the wiring length L where the electromigration according to the current density of the current flowing in each wiring line can be suppressed. More specifically, each of the upper-layer wiring line 11 and the lower-layer wiring line 12 is divided to be a length L satisfying the following expression:

i×L≦C (1).

Here, the constant C is a constant determined, so that the back flow effect can be realized with respect to the relationship between the current density i and the wiring length L, by an experiment, a simulation, and the like on the basis of: the material and a sectional area of the wiring line; the material of the insulating film around the wiring line; a forming method of the wiring line and the insulating film; and the like. In addition, the current density i may exceed the worst case current limitation value. However, the current density i is determined to be a smaller value than the current density or the current value at which the fusing of the wiring line due to the Joule heat occurs.

In the example of the drawings, the upper-layer wiring line 11 and the lower-layer wiring line 12 are divided at the division positions 18 and 19 so that the current densities i₁ and i₂ of the currents flowing in each wiring line and the wiring lengths L₁ and L₂ can satisfy relationships of: i₁×L₁≦C; and i₂×L₂≦C. For example, when the current density i₁ is determined by a circuit simulation and the like, the wiring length L₁ is determined so as to satisfy “L₁≦C/i₁” based on the expression (1), and the division position 18 is set so as to satisfy the determined wiring length L₁.

In this manner, when the wiring lengths L₁ and L₂ of the upper-layer wiring line 11 and the lower-layer wiring line 12 are limited on the basis of expression (1), the back flow effect can be realized in the upper-layer wiring line 11 and the lower-layer wiring line 12. Accordingly, even in the case where the current densities i₁ and i₂ exceed a predetermined current limitation value, occurrence of the electromigration can be suppressed due to the back flow effect, thereby being able to extend the lifetime of the wiring line. That is, even in the case where the current densities i₁ and i₂ exceed the predetermined current limitation value, the correction such as the extension of the wiring width W and the increasing of the number of wiring lines is not required. As the result, the problems: that an area of the circuit becomes large; that a design time is lengthened by repeating the correction and confirmation; that the correction is hard to be carried out in a large-scale circuit when balancing with other parts is considered; and the like can be avoided.

On this occasion, it is preferred that the plurality of vias 15 are arranged sufficiently in number. This is because the wiring lengths L₁ and L₂ can be adjusted to be a desired length in the above-mentioned manner by cutting the upper-layer wiring line 11 and/or the lower-layer wiring line 12 between the desired vias 15. In this manner, flexibility of the change of the layout can be improved. The above-mentioned arrangement occurs approximately once in a range from 100 nm to 1000 nm, for example.

In the example of the drawings, the power source wiring line 2 is double-layered (the upper-layer wiring line 11 and the lower-layer wiring line 12). However, the embodiment is not limited to the example, and the wiring line may have further more layers connected each other by the vias.

Additionally, in the example of the drawings, the power source wiring line 2 has been described. However, the embodiment is not limited to the example, and can be also applied to other kinds of wiring lines in the same manner.

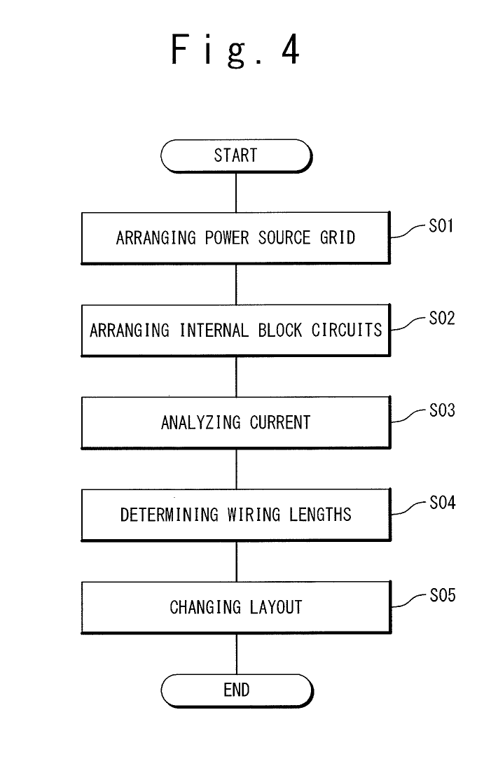

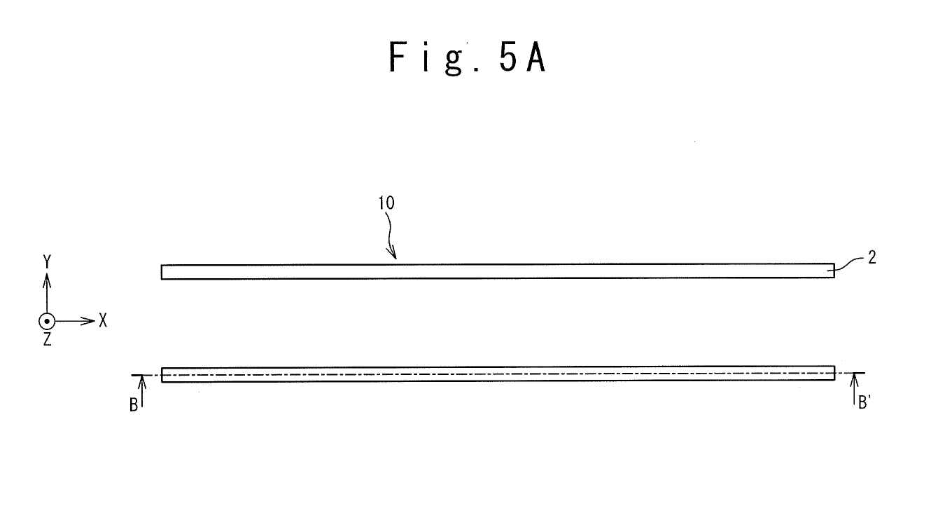

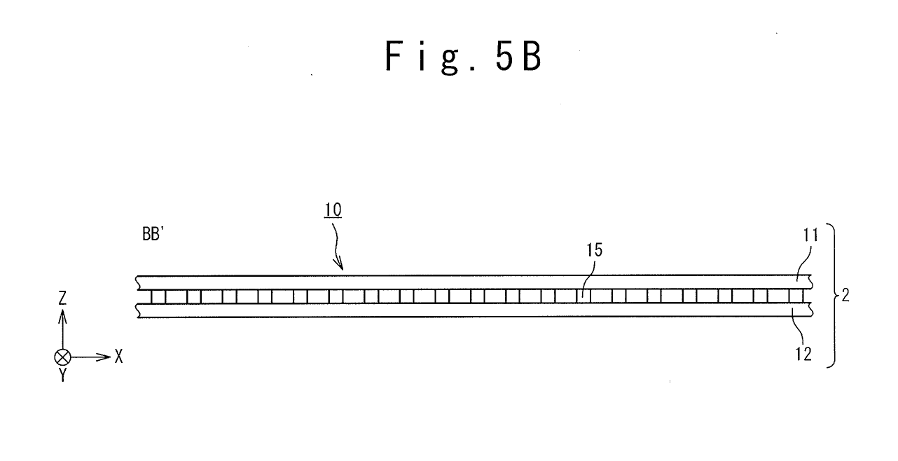

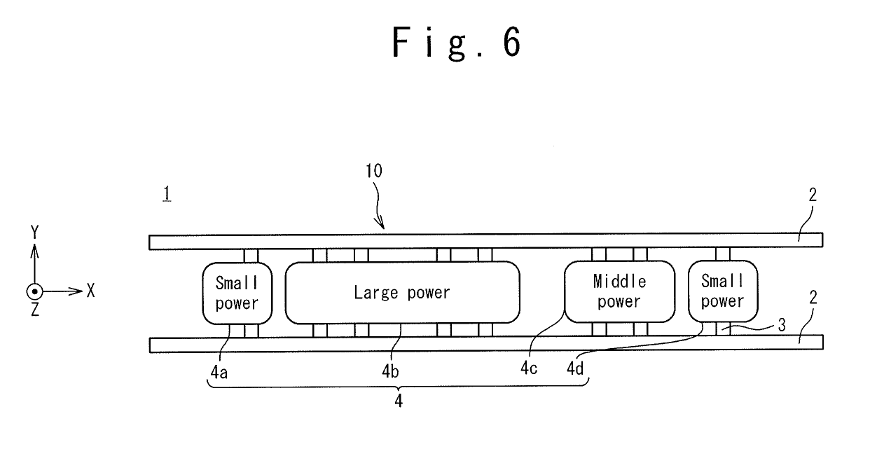

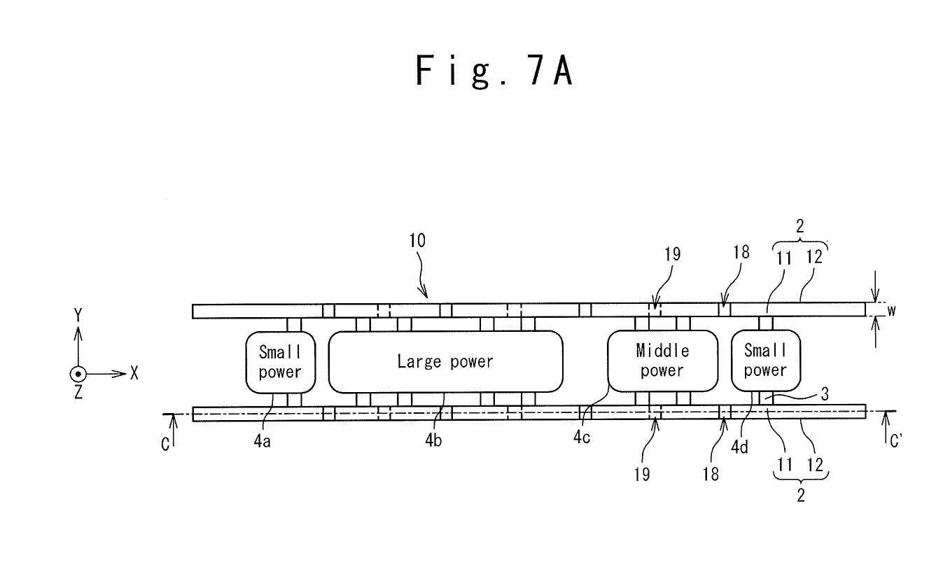

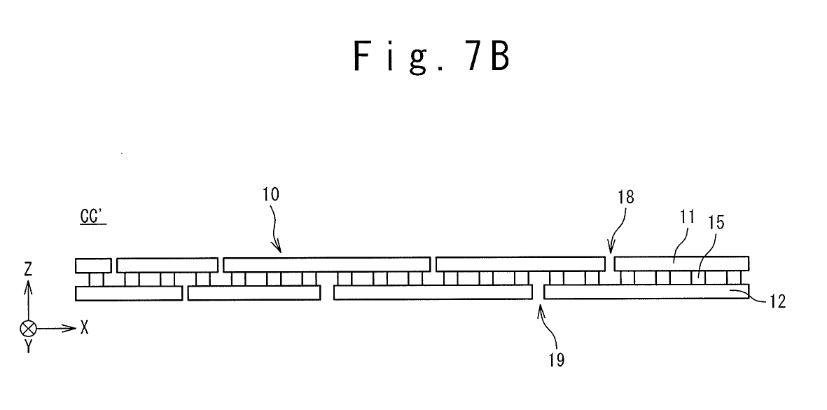

Next, an operation of the design apparatus of the semiconductor device according to the embodiment of the present invention (a design method of the semiconductor device) will be described. FIG. 4 is a flowchart showing an operation of the design apparatus according to the embodiment of the present invention (the design method of the semiconductor device). FIGS. 5A, 5B, 6, 7A, and 7B are schematic views showing one example of a configuration of the semiconductor device in respective design steps using the design apparatus of the semiconductor device according to the embodiment of the present invention. However, FIG. 5A shows a plane view, FIG. 5B shows a BB′ sectional view in FIG. 5A, FIG. 6 shows a plane view, FIG. 7A shows a plane view, and FIG. 7B shows a CC′ sectional view in FIG. 7A, respectively.

At first, the power source grid wiring section 31 configures a basic structure of the power source grid 10, for example, to be FIG. 5A and FIG. 5B on the basis of arrangement information and connection information of the semiconductor device (step S01). In this manner, the power source wiring lines 2 are arranged in the lattice shape (here, the drawings show a part of the wiring lines). Each of the power source wiring lines 2 has a structure where the upper-layer wiring line 11 and the lower-layer wiring line 12 constituting the double-layered wiring line are arranged to be parallel with each other and are connected in parallel by a plurality of vias 15 with the optimal number. In this process, layout data showing the arrangement of the power source grid 10 is created (step S01).

Next, the internal block circuit placement section 32 arranges the plurality of internal block circuits 4 in the inside of the mesh (the lattice) of the power source 10 on the basis of the arrangement information and the connection information of the semiconductor device, for example, as shown in FIG. 6 (step S02). In this manner, the plurality of internal block circuits 4 is connected to the power source grid 10 through the power source leading wiring lines 3. In the example of the drawings, the internal block circuits 4a to 4d are arranged; however, the circuits do not necessarily consume the same power. For example, the internal block circuits 4a and 4d consume low power, the internal block circuit 4c consumes middle power, and the internal block circuit 4b consumes high power. In this process, layout data showing the arrangement of the internal block circuits 4 is created (step S02).

Subsequently, the current analysis section 33 creates a netlist from the created layout data, and executes circuit simulations. The current analysis section 33 analyzes a current in the circuit simulation on the basis of power consumption and an operation rate in each of the plurality of internal block circuits 4 to detect a position at which the current density exceeds the worst case current limitation value (step S03). On this occasion, the current density is calculated, for example, assuming that the power source wiring line 2 is a single-layer wiring line (with a single-layer section area), such as only the upper-layer wiring line 11 or only the lower-layer wiring line 12.

Next, the wiring length determination section 34 determines, in the portion where the current density exceeds the worst case current limitation value (or a surrounding portion including the portion), wiring lengths of the upper-layer wiring line 11 and the lower-layer wiring line 12 in the power source wiring line 2 such that the electromigration caused by the current density can be suppressed due to the back flow effect (step S04). That is, the wiring lengths of the upper-layer wiring line 11 and the lower-layer wiring line 12 are determined so that a product of the current density and the wiring length in the corresponding portion of the power source wiring line (and the power source leading wiring line 3 connecting the internal block circuit 4 and the wiring line) can be equal to or less than a preliminarily set value (so that the above-mentioned expression (1) can be satisfied). Or, the wiring length determination section 34 determines the wiring lengths of the upper-layer wiring 11 and the lower-layer wiring 12 are determined so that the current density in the corresponding portion of the power source wiring 2 (and the power source leading wiring line 3 connecting the internal block circuit 4 and the wiring line) can be equal to or less than a limitation value which is set base on a wiring length (so that the expression “i₁≦C/L₁” can be satisfied).

Subsequently, as shown in FIGS. 7A and 7B, the layout change section 35 divides the upper-layer wiring line 11 and the lower-layer wiring line 12 of each of the power source wiring lines 2 so that the wiring lengths of the upper-layer wiring line 11 and the lower-layer wiring line 12 in each of the power source wiring lines 2 can be the determined wiring lengths (step S05). In the example of the drawings, in order to realize the determined wiring lengths satisfying the expression (1), the upper-layer wiring line 11 is divided at four positions and the lower-layer wiring line 12 is divided at three positions, and thus the respective wiring lengths are shorted. Accordingly, even in the case where the current density is high, the influence of the EM can be suppressed by the back flow effect. On this occasion, the layout change section 35 changes the layout data of the power source grid 10 so as to be the layout where the upper-layer wiring line 11 and the lower-layer wiring line 12 of each of the power source wiring lines 2 are divided at the positions of the determined wiring lengths. Meanwhile, in the case where the upper-layer wiring line 11 and/or the lower-layer wiring line 12 cannot be divided at the position of the determined wiring lengths due to the relationship between a position of the via 15 and a position of the power source leading wiring line 3, the wiring lengths are shortening more. On this occasion, the wiring layer to be divided (for example, the upper-layer wiring line 11) is connected to the other wiring layer (for example, the lower-layer wiring line 12) by the vias 15, and accordingly the function of the power source wiring line 2 (the power source grid 10) is never lost electrically.

In the above-mentioned operation, the internal block circuits 4 can be arranged in the power source grid 10. Thus the operation of the design apparatus of the semiconductor device (the design method of the semiconductor device) according to the embodiment can be carried out.

Meanwhile, at step S3, in the calculation of the current density, the calculation can be carried out, assuming that the power source wiring line 2 is a double-layer wiring line (with a double-layer section area) of the upper-layer wiring line 11 and the lower-layer wiring line 12). In this case, the current having the current density twice as much as the calculated current density will accordingly flow to each of the lower-layer wiring 12 and the upper-layer wiring 11 due to the division of: the upper-layer wiring line 11 and the lower-layer wiring line 12. At step S4, the wiring lengths of the lower-layer wiring line 12 and the upper-layer wiring line 11 are calculated on the basis of the current density twice as much as the calculated current density.

In the present embodiment, even when there is the power source wiring line in which the current density exceeds the worst case current limitation value, the wiring lengths of the upper-layer wiring line and the lower-layer wiring line of the power source wiring line are adjusted so as to satisfy a predetermined condition, depending on the current density. As the result, the EM in the power source wiring line can be suppressed due to the back flow effect caused in the wiring length.

On this occasion, the wiring lengths are adjusted by dividing the already existing upper-layer wiring line and lower-layer wiring line in the power source wiring line. As the result, the change of the configuration of wiring lines such as the extension of the wiring width of the power source wiring lines 2 and the increasing of the number of wiring lines is not required. Accordingly, the problems such as the increasing of the area of the circuit, the lengthening of the design time by repeating the correction and confirmation, and the difficulty of the correction in a large-scale circuit due to the balancing with other portions are not caused.

As described above, the power source wiring lines 2 configure the net-shaped grid (the power source grid 10). Regarding a circumference of the net where the power consumption is large and where the current value (the current density) flowing to the power source wiring line 2 is large, by shortening the power source wiring line 2, the reliability against the EM can be improved without largely changing the layout.

It is apparent that the present invention is not limited to the above embodiment, but may be modified and changed without departing from the scope and spirit of the invention.

Although the present invention has been described above in connection with several exemplary embodiments thereof, it would be apparent to those skilled in the art that those exemplary embodiments are provided solely for illustrating the present invention, and should not be relied upon to construe the appended claims in a limiting sense.

What is claimed is:

1. A design method of a semiconductor device comprising:
arranging grid wiring which includes a plurality of wiring lines arranged in parallel to each other and a plurality of vias connecting said plurality of wiring lines with each other;
arranging a plurality of internal circuits connected to said grid wiring;
calculating a current density of a current flowing in said grid wiring by said plurality of internal circuits; and
dividing each of said plurality of wiring lines into portions each having a wiring length such that electromigration corresponding to said current density is suppressed.

2. The design method of a semiconductor device according to claim 1, wherein said dividing step includes:
determining said wiring length for said each of said plurality of wiring lines such that a product of said current density and said wiring length is equal to or less than a preliminarily set value, and
dividing said each wiring line into said portions based on said wiring length for said each of said plurality of wiring lines

3. The design method of a semiconductor device according to claim 2, wherein said each wiring line is a power source wiring line.

4. The design method of a semiconductor device according to claim 1, wherein said plurality of wiring lines is composed of a double or more-layer wiring line.

5. The design method of a semiconductor device according to claim 1, wherein said grid wiring includes:
a power source terminal supplied with a power source,
wherein said dividing step includes:
dividing said each of said plurality of wiring lines into said portions such that at least one current path is formed between said power source terminal and said plurality of internal circuits.

6. A non-transitory computer-readable recording medium in which a computer-readable program code is stored for realizing a design method of a semiconductor device, said design method comprising:
arranging grid wiring which includes a plurality of wiring lines arranged in parallel to each other and a plurality of vias connecting said plurality of wiring lines with each other;
arranging a plurality of internal circuits connected to said grid wiring;
calculating a current density of a current flowing in said grid wiring by said plurality of internal circuits; and
dividing each of said plurality of wiring lines into portions each having a wiring length such that electromigration corresponding to said current density is suppressed.

7. The non-transitory computer-readable recording medium according to claim 6, wherein said dividing step in said design method includes:
determining said wiring length for said each of said plurality of wiring lines such that a product of said current density and said wiring length is equal to or less than a preliminarily set value, and
dividing said each wiring line into said portions based on said wiring length for said each of said plurality of wiring lines.

8. The non-transitory computer-readable recording medium according to claim 7, wherein said each wiring line is a power source wiring line.

9. The non-transitory computer-readable recording medium according to claim 6, wherein said plurality of wiring lines is composed of a double or more-layer wiring line.

10. The non-transitory computer-readable recording medium according to claim 6, wherein said grid wiring includes:
a power source terminal supplied with a power source,
wherein said dividing step in said design method includes:
dividing said each of said plurality of wiring lines into said portions such that at least one current path is formed between said power source terminal and said plurality of internal circuits.

11. A design apparatus of a semiconductor device comprising:
a grid wiring section configured to arrange grid wiring which includes a plurality of wiring lines arranged in parallel to each other and a plurality of vias connecting said plurality of wiring lines with each other;
a circuit placement section configured to arrange a plurality of internal circuits connected to said grid wiring;
a current analysis section configured to calculate a current density of a current flowing in said grid wiring by said plurality of internal circuits; and
a layout adjustment section configured to divide each of said plurality of wiring lines into portions each having a wiring length such that electromigration corresponding to said current density is suppressed.

12. The design apparatus of a semiconductor device according to claim 11, wherein said layout adjustment section includes:
a wiring length determination section configured to determine said wiring length for said each of said plurality of wiring lines such that a product of said current density and said wiring length is equal to or less than a preliminarily set value, and
a layout change section configured to divide said each wiring line into said portions based on said wiring length for said each of said plurality of wiring lines.

13. The design apparatus of a semiconductor device according to claim 12, wherein said each wiring line is a power source wiring line.

14. The design apparatus of a semiconductor device according to claim 11, wherein said plurality of wiring lines is composed of a double or more-layer wiring line.

15. The design apparatus of a semiconductor device according to claim 11, wherein said grid wiring includes:
a power source terminal supplied with a power source,
wherein said layout adjustment section divides said each of said plurality of wiring lines into said portions such that at least one current path is formed between said power source terminal and said plurality of internal circuits.

16. A semiconductor device comprising:
grid wiring configured to include a plurality of wiring lines arranged in parallel to each other and a plurality of vias connecting said plurality of wiring lines with each other; and
a plurality of internal circuits configured to be connected to said grid wiring;
wherein a current flows in said grid wiring by said plurality of internal circuits,
wherein each of said plurality of wiring lines is divided into portions each having a wiring length such that electromigration corresponding to a current density of said current is suppressed.

17. The semiconductor device according to claim 16, wherein said wiring length for said each of said plurality of wiring lines is set such that a product of said current density and said wiring length is equal to or less than a preliminarily set value.

18. The semiconductor device according to claim 16, wherein said each wiring line is a power source wiring line.

19. The semiconductor device according to claim 16, wherein said plurality of wiring lines is composed of a double or more-layer wiring line.
